(19) United States
(12) Patent Application Publication
(10) Pub. No.: US 2026/0006811 A1
(43) Pub. Date: Jan. 1, 2026

(54) GATE-ALL-AROUND DEVICES

(71) Applicant: Taiwan Semiconductor Manufacturing Company, Ltd., Hsinchu (TW)

(72) Inventors: Mu-Chieh Chang, Zhubei City (TW); Wen-Kai Lin, Hsinchu City (TW); Che-Hao Chang, Hsinchu City (TW); Tai-Chun Huang, Hsin-Chu City (TW); Wei-Yang Lee, Taipei City (TW)

(21) Appl. No.: 18/758,968

(22) Filed: Jun. 28, 2024

(51) Int. Cl. H01L 29/66; H01L 29/06; H01L 29/417; H01L 29/423; H01L 29/775; H01L 29/786

(52) U.S. Cl. CPC H10D 30/014; H10D 30/43; H10D 62/116; H10D 64/017; H10D 64/258; H10D 30/6735; H10D 30/6757; H10D 62/121

(57) ABSTRACT

A method of the present disclosure includes forming a stack including channel layers interleaved by sacrificial layers, patterning the stack to form a fin-shaped structure, forming an isolation feature, forming a dummy gate stack over a channel region of the fin-shaped structure, depositing a gate spacer layer over the dummy gate stack, recessing a source/drain region of the fin-shaped structure, selectively removing the sacrificial layers to release the channel layers channel members, depositing a dummy layer over the channel members, selectively and partially recessing the dummy layer to form inner spacer recesses, depositing a first inner spacer layer and a second inner spacer layer over the inner spacer recesses, etching back the first inner spacer layer and the second inner spacer layer to form inner spacer features, forming a source/drain feature, removing the dummy layer, and forming a gate structure to wrap around each of the plurality of channel members.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-25 illustrate fragmentary cross-sectional views of a work-in-progress (WIP) structure during a fabrication process according to the method of FIG. 1, according to one or more aspects of the present disclosure.

FIG. 26 illustrates an enlarged cross-sectional view of an inner spacer feature in FIG. 17, according to one or more aspects of the present disclosure.

FIG. 27 illustrates an enlarged cross-sectional view of an inner spacer feature in FIG. 25, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to GAA transistors and fabrication methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. During the removal of the sacrificial materials, inner spacer features function to contain the etching process to define a profile of the gate structure and to protect the epitaxial source/drain features from being etched. When etching selectivity between the inner spacer features and the sacrificial materials is less than satisfactory, the profile of the gate structure may be inconsistent and the epitaxial source/drain features may be damaged.

The present disclosure provides methods for forming a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. A first inner spacer layer and a second inner spacer layer are sequentially deposited over the inner spacer recesses. The first inner spacer layer may include aluminum oxide, polyethylene, polypropylene, or a boron-containing dielectric layer. The second inner spacer may include silicon carbonitride, silicon oxycarbonitride, silicon nitride, silicon oxycarbide, or silicon oxynitride. The deposited first inner spacer layer and second inner spacer layer are etched back to form inner spacer features. The etch back may etch the first inner spacer layer faster than it etches the second inner spacer layer such that the second inner spacer layer protrudes toward the source/drain recesses. Source/drain features are then formed over the source/drain recesses. After selective removal of the dummy gate stack, the dummy layer is selectively removed to release the channel members again. A gate structure is then formed to wrap around each of the channel members. A composition of the first inner spacer layer is selected such that it is not substantially etched when the dummy layer is etched away.

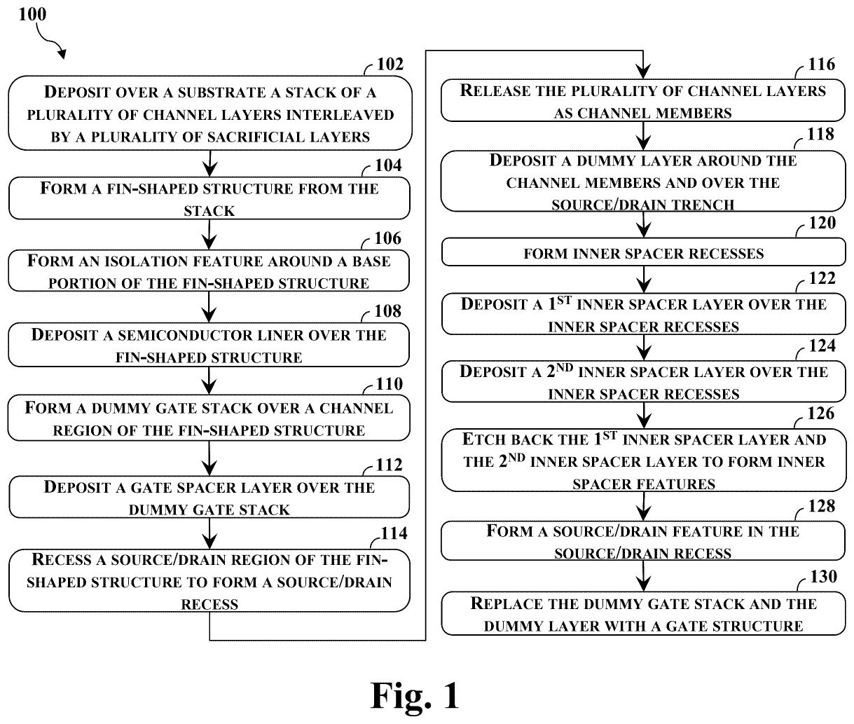

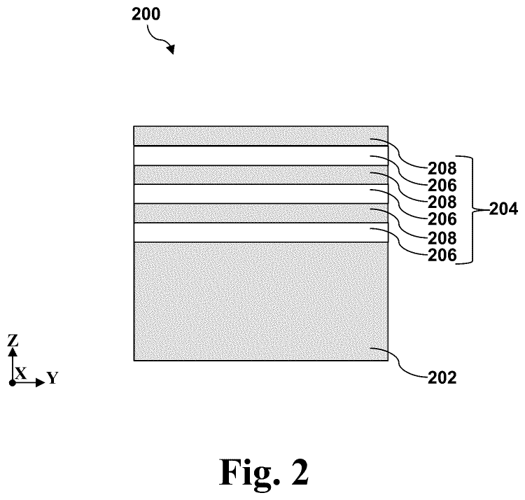

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-26, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-26 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

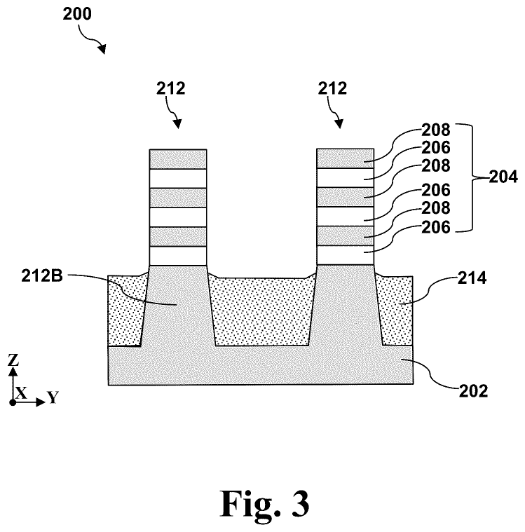

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202 and the patterned stack 204 disposed directly over the base fin structure 212B.

Referring to FIGS. 1 and 3, method 100 includes a block 106 where an isolation feature 214 is formed around a base fin structure 212B of the fin-shaped structures 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

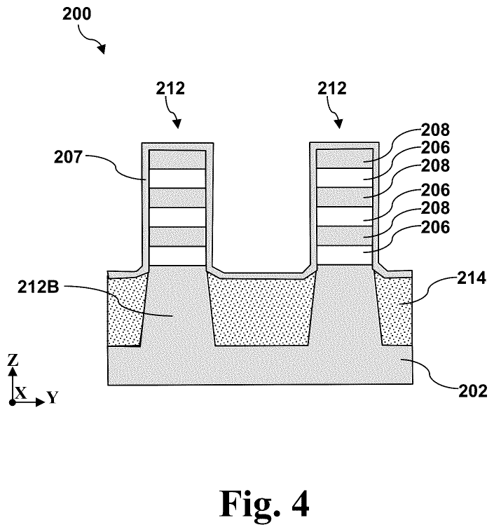

Referring to FIGS. 1 and 4, method 100 includes a block 108 where a semiconductor liner 207 is deposited over the fin-shaped structure 212. After the formation of the isolation feature 214, a semiconductor liner 207 may be deposited over the WIP structure 200, including over the isolation feature 214, over a top surface of the fin-shaped structure 212, and along sidewalls of the fin-shaped structure 212. The semiconductor liner 207 functions to protect the sidewalls of the sacrificial layers 206 as they can sustain undesirable damages during the fabrication processes. In some embodiments, the semiconductor liner 207 may include silicon (Si). In some implementations, the semiconductor liner 207 may be deposited using PVD, CVD, or atomic layer deposition (ALD).

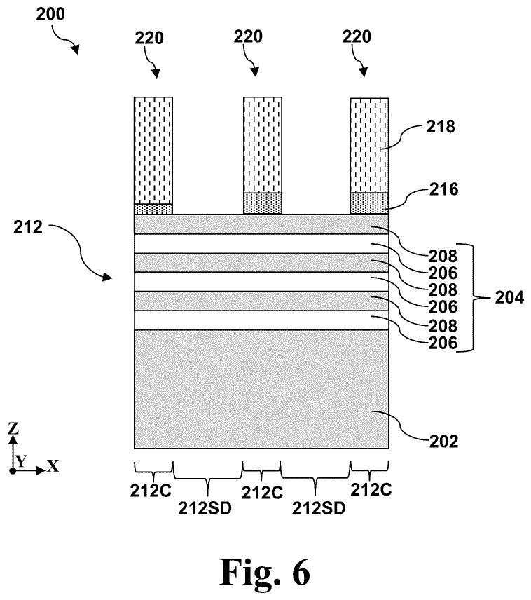

Referring to FIGS. 1, 5 and 6, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

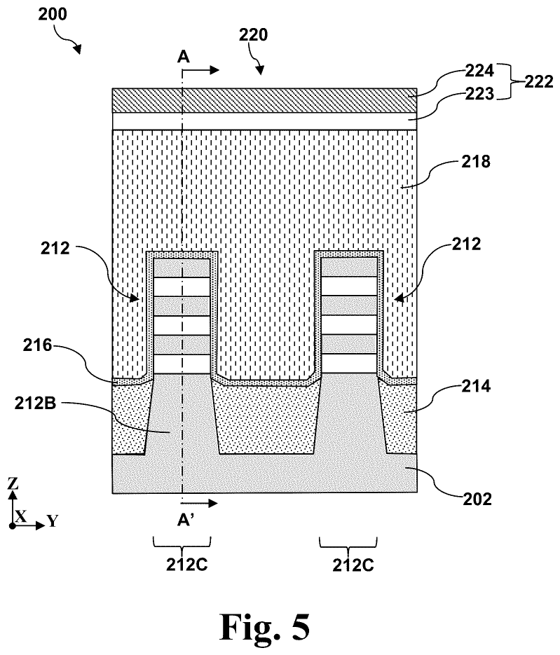

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

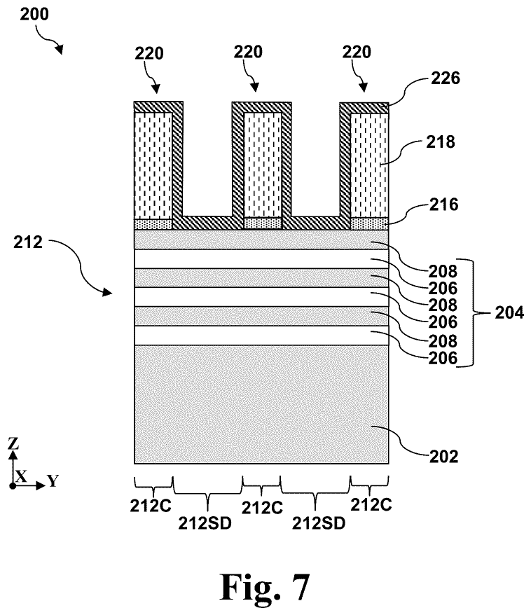

Referring to FIGS. 1 and 7, method 100 includes a block 112 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

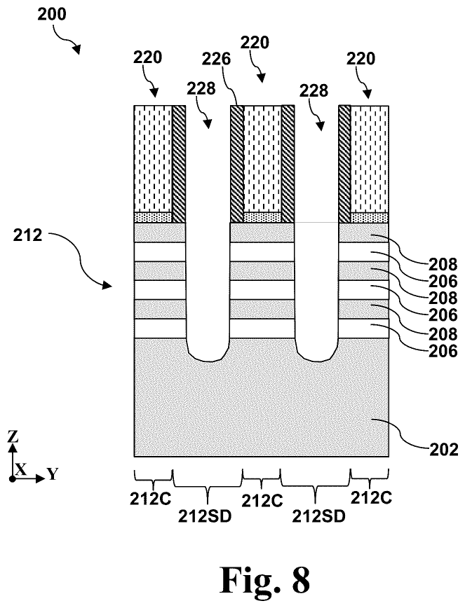

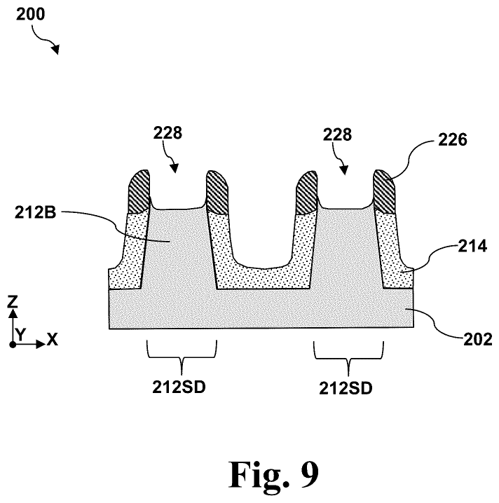

Referring to FIGS. 1, 8 and 9, method 100 includes a block 114 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 9, which includes a fragmentary cross-sectional view across two adjacent source/drain regions 212SD. As shown in FIG. 9, over the source/drain regions 212SD, the majority of the fin-shaped structure 212 is etched away and a top surface of the base fin structure 212B is exposed in the source/drain region 212SD. Because the gate spacer layer 226 etches at a slower rate than the fin-shaped structure 212, the gate spacer layer 226 in the source/drain region 212SD rises above the top surface of the base fin structure 212B.

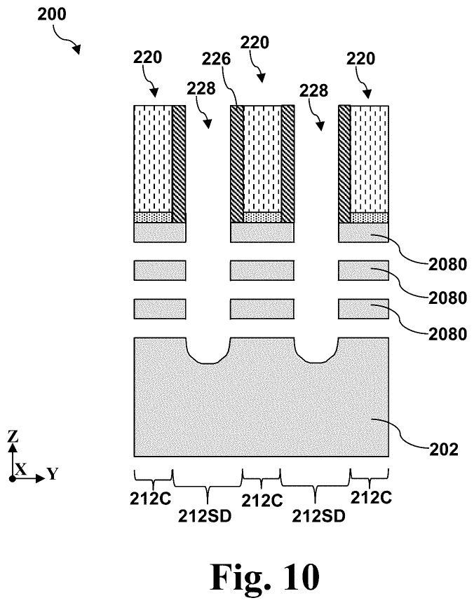

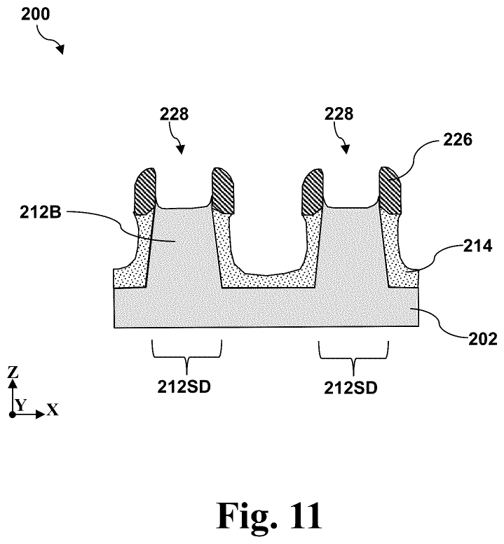

Referring to FIGS. 1, 10 and 11, method 100 includes a block 116 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 10. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Referring to FIG. 11. at block 116, the base fin structures 212B in the source/drain regions 212SD are not substantially etched.

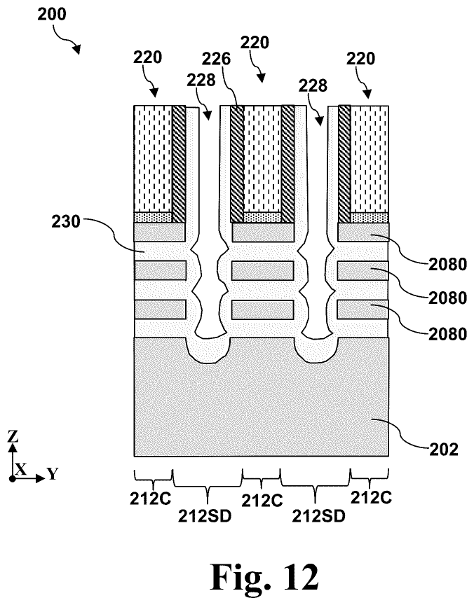

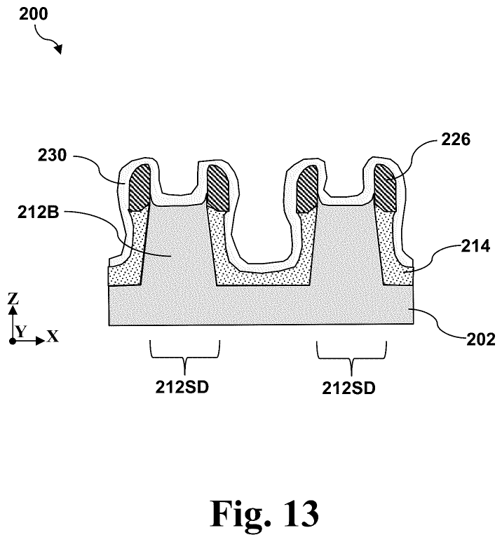

Referring to FIGS. 1, 12 and 13, method 100 includes a block 118 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 12, the dummy layer 230 fills the space among the channel members 2080 and covers end sidewalls of the channel members 2080. Additionally, the dummy layer 230 is in direct contact with a sidewall of the gate spacer layer 226 and a top surface of the substrate 202. Reference is made to FIG. 13, which includes a fragmentary cross-sectional view across two adjacent source/drain regions 212SD. As shown in FIG. 13, the dummy layer 230 extends conformally over the isolation feature 214, sidewalls of the gate spacer layer 226, and top surfaces of the gate spacer layer 226. Depending on the design, the channel members 2080 may take form of nanowires, nanosheets, or other nanostructures.

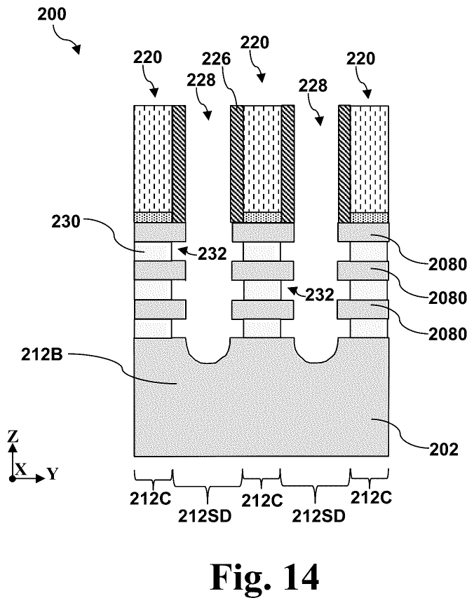

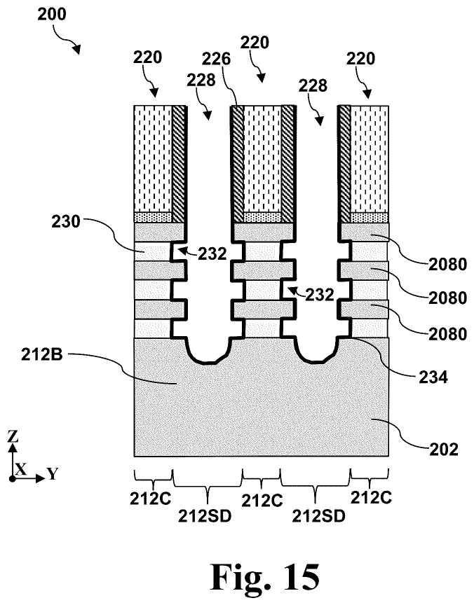

Referring to FIGS. 1 and 14, method 100 includes a block 120 where inner spacer recesses 232 are formed. Referring to FIG. 15, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

Referring to FIGS. 1 and 15, method 100 includes a block 122 where a first inner spacer layer 234 is deposited over the inner spacer recesses 232. According to the present disclosure, the first inner spacer layer 234 is formed of a material that is substantially unetched when the dummy layers 230 is removed. That is, the first inner spacer layer 234 is formed of a material that allows the dummy layers 230 to be selectively removed. In some embodiments, the first inner spacer layer 234 includes metal oxide, such as polycrystalline aluminum oxide. As the dummy layer 230 is formed of silicon oxide, the removal of dummy layer 230 in a subsequent step may include use of hydrofluoric acid or hydrogen fluoride. It has been observed that crystalline or polycrystalline aluminum oxide experience slow etching by hydrofluoric acid. When the first inner spacer layer 234 includes polycrystalline aluminum oxide, it may be deposited using atomic layer deposition (ALD). In some embodiments, an anneal process may be performed after the deposition of the first inner spacer layer 234 to increase crystallinity of the first inner spacer layer 234. Because source/drain features and gate structures have not been formed at this point, the anneal process is unlikely to result in any undesirable side effect, such as change in doping profile or threshold voltage drift. In some instances, the anneal process may include an anneal temperature between about 200° C. and about 500° C. When the first inner spacer layer 234 includes polycrystalline aluminum oxide, it has a dielectric constant between about 8 and about 9.5.

In some alternative embodiments, the first inner spacer layer 234 includes a polymeric material, such as polyethylene (PE) or polypropylene (PP). While polymeric materials may be susceptible to dry etching that involves use of plasma, they can be quite resistant to acid, such as hydrofluoric acid that is used to etch the dummy layer 230. In these embodiments, in order to deposit the polymeric materials over the WIP structure 200, surfaces of the WIP structure 200 may be subject to a plasma treatment to increase the population of dangling hydroxyl bonds on the surfaces. In some instances, the plasma treatment may include use of oxygen plasma. After the surface plasma treatment, monomers of the polymeric material, such as ethylene or propylene are allowed to come in contact and react with the dangling bond in presence of at least one catalyst. In one example process, a first catalyst is first used to promote reaction between the monomers and the dangling bonds and then a second catalyst is used to promote polymerization of the monomer. When the first inner spacer layer 234 includes PE or PP, it has a dielectric constant between about 2.2 and about 2.6.

In still some alternative embodiments, the first inner spacer layer 234 includes a boron-containing dielectric material, such as boron carbon oxynitride (BCNO) or boron-doped silicon oxycarbonitride (B—SiOCN). In these embodiments, the boron contents allow the boron-containing dielectric material to be resistant to the chemistry that etches the dummy layer 230. Additionally, boron carbon oxynitride (BCNO) may have a dielectric constant between about 1.2 and about 3.7, which is advantageous in reducing parasitic capacitance. In some implementations, when the first inner spacer layer 234 includes the boron-containing dielectric material, the first inner spacer layer 234 may be deposited using chemical vapor deposition (CVD) or atomic layer deposition.

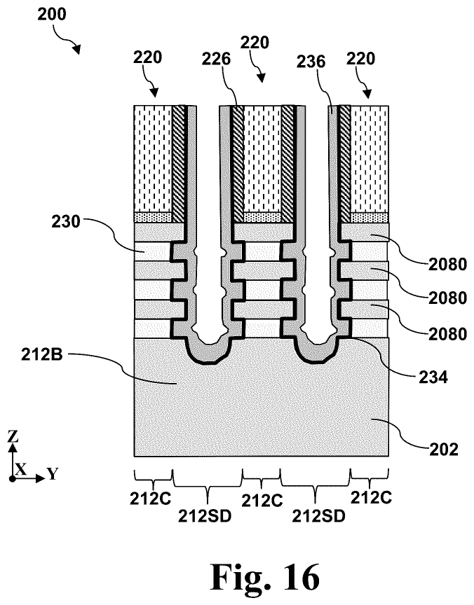

Referring to FIGS. 1 and 16, method 100 includes a block 124 where a second inner spacer layer 236 is deposited over the inner spacer recesses 232. At block 124, the second inner spacer layer 236 is deposited over the first inner spacer layer 234. A composition of the second inner spacer layer 236 is selected such that the etching back operation in subsequent block 126 etches the second inner spacer layer 236 at a smaller rate than it etches the first inner spacer layer 234. In some embodiments, the second inner spacer layer 236 may include silicon carbonitride (SiCN), silicon oxycarbonitride (SiOCN), silicon nitride (SiN), silicon oxycarbide (SiOC), or silicon oxynitride (SiON). In some implementations, the second inner spacer layer 236 may be deposited using CVD or ALD. The second inner spacer layer 236 may have a dielectric constant between about 3.5 and about 6. When the first inner spacer layer 234 includes polycrystalline aluminum oxide, the dielectric constant of the second inner spacer layer 236 is smaller than the dielectric constant of the first inner spacer layer 234. However, when the first inner spacer layer 234 includes boron carbon oxynitride, PE, PP, or other polymeric materials, the dielectric constant of the second inner spacer layer 236 is greater than the dielectric constant of the first inner spacer layer 234. When the first inner spacer layer 234 includes boron-doped silicon oxycarbonitride, the dielectric constant of the second inner spacer layer 236 may be substantially similar to the dielectric constant of the first inner spacer layer 234.

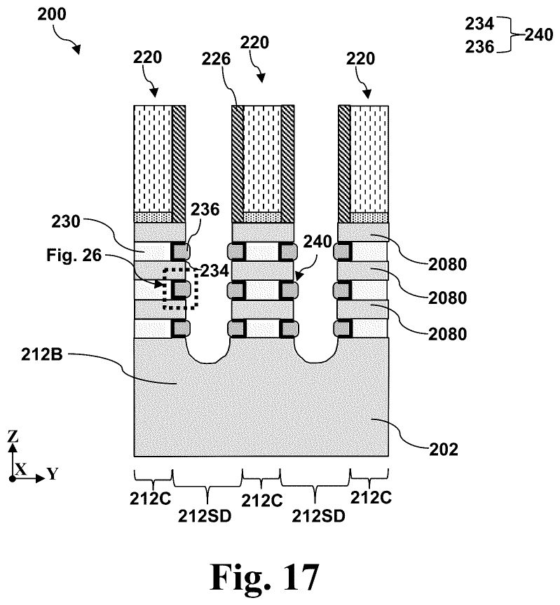

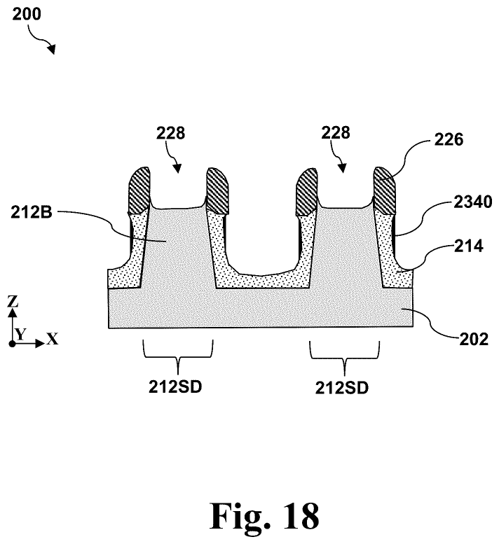

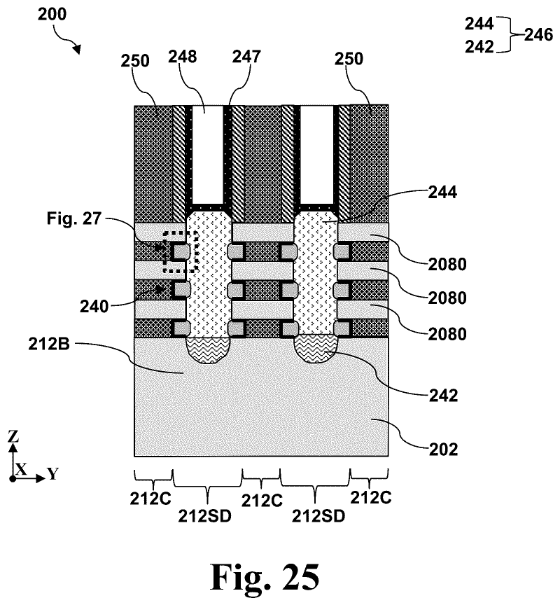

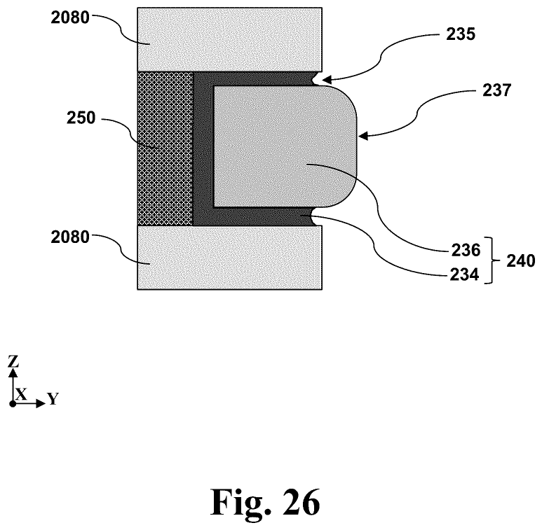

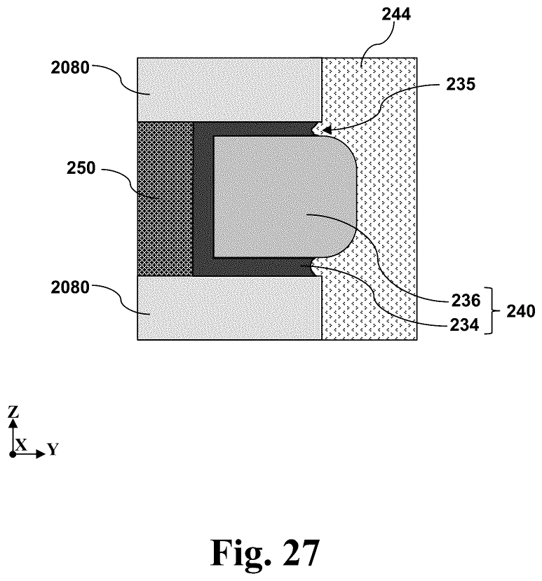

Referring to FIGS. 1, 17 and 18, method 100 includes a block 126 where the first inner spacer layer 234 and the second inner spacer layer 236 are etched back to form inner spacer features 240 over the inner spacer recesses 232. Referring to FIG. 17, the deposited first inner spacer layer 234 and second inner spacer layer 236 are then etched back to expose sidewalls of the channel members 2080, thereby forming inner spacer features 240 in the inner spacer recesses 232. In some embodiments, the etching back at block 126 may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. As shown in FIG. 17, the dry etch process, while being anisotropic to some extent, etches the first inner spacer layer 234 at a greater rate. For example, when the first inner spacer layer 234 includes polycrystalline aluminum oxide, the chlorine containing chemistry, such as boron trichloride (BCl₃), chlorine (Cl₂), hydrogen chloride (HCl), etches the first inner spacer layer 234 faster than it does the second inner spacer layer 236. When the first inner spacer layer 234 includes polyethylene (PE) or polypropylene (PP), the plasma energy causes the dry etch to etch the first inner spacer layer 234 faster than it does the second inner spacer layer 236. When the first inner spacer layer 234 includes a boron-containing dielectric material, the fluorine-containing chemistry, such as nitrogen trifluoride (NF₃), carbon tetrafluoride (CF₄), sulfur hexafluoride (SF₆), may etch the first inner spacer layer 234 faster than it does the second inner spacer layer 236. The etching rate differential may lead to an over-etch of the first inner spacer layer 234 and an under-etch of the second inner spacer layer 236. In at least some embodiments, each of the inner spacer features 240 may have a cross-sectional profile shown in FIG. 25. Reference is made to FIG. 26. The over-etch of the first inner spacer layer 234 may result in a sidewall recess 235. In some instances, sidewalls of the first inner spacer layer 234 do not extend all the way to be planar with sidewalls of the channel members 2080. The under-etch of the second inner spacer layer 236 may result in a rounded protrusion 237 that extends toward the source/drain trench 228 (shown in FIG. 14). When formation of source/drain features (to be described below) includes both a deposition element and an etching element, the rounded protrusion 237 provides additional protection and cushion in case the etching element removes too much of the inner spacer features 240. Reference is made to FIG. 18, which includes a fragmentary cross-sectional view across two adjacent source/drain regions 212SD. As shown in FIG. 18, the etch back may not completely remove a sidewall portion 2340 of the first inner spacer layer 234 along sidewalls of the isolation feature 214.

Referring to FIGS. 1, 19 and 20, method 100 includes a block 128 where a source/drain feature 246 is formed over the source/drain region 212SD. While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

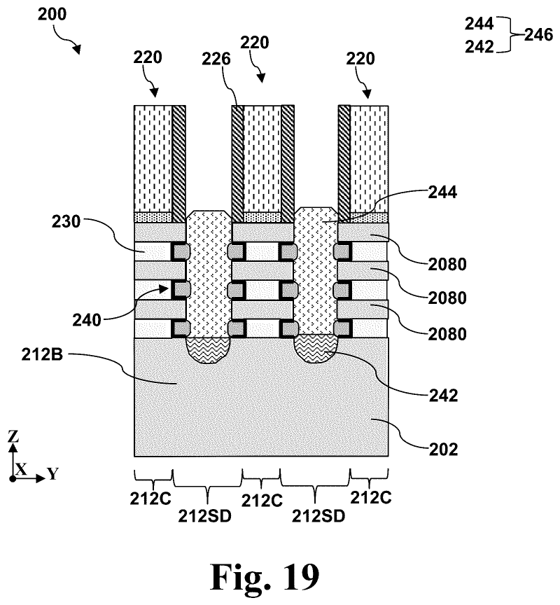

Reference is made to FIG. 19. In some embodiments, a source/drain feature 246 includes a bottom epitaxial feature 242 and a main epitaxial feature 244 over the bottom epitaxial feature 242. The source/drain feature 246 may be n-type or p-type. When the source/drain feature 246 is n-type, the bottom epitaxial feature 242 may include undoped silicon (Si) or undoped silicon germanium (SiGe) and the main epitaxial feature 244 may include silicon (Si) and an n-type dopant, such as phosphorus (P), arsenic (As), antimony (Sb), or a combination thereof. When the source/drain feature 246 is p-type, the bottom epitaxial feature 242 may include undoped silicon (Si) or undoped silicon germanium (SiGe) and the main epitaxial feature 244 may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature 242 may include a counter dopant to reduce leakage into the bulk substrate 202. For example, the bottom epitaxial feature 242 in the n-type source/drain feature 246 may include a p-type dopant, such as boron (B). For another example, the bottom epitaxial feature 242 in the p-type source/drain feature 246 may include an n-type dopant, such as phosphorus (P), arsenic (As), or antimony (Sb). The source/drain feature 246 may be formed using vapor-phase epitaxy (VPE), ultra-high vacuum CVD (UHV-CVD), or molecular beam epitaxy (MBE). Doping of the source/drain features 246 may be achieved with in-situ doping.

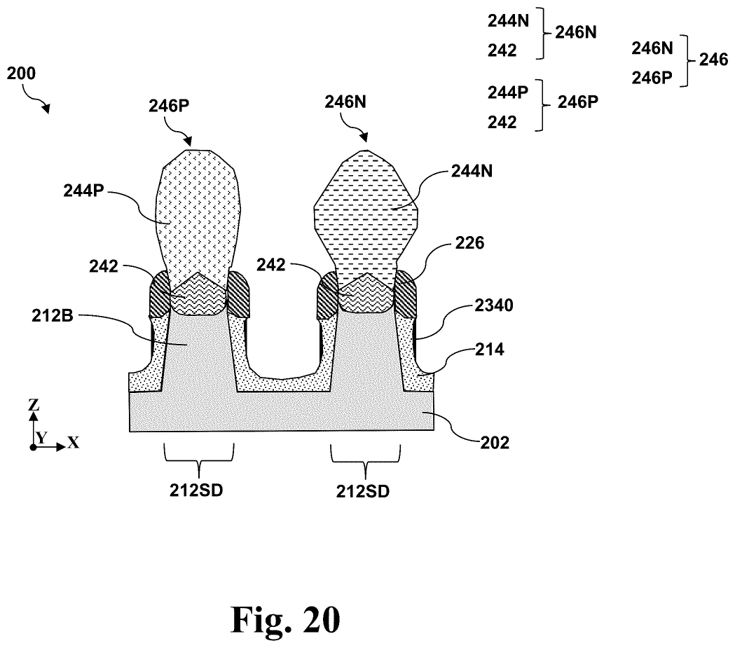

Reference is made to FIG. 20, which includes a fragmentary cross-sectional view across two adjacent source/drain regions 212SD. In some embodiments represented in FIG. 20, an n-type source/drain feature 246N may be adjacent a p-type source/drain feature 246P. The n-type source/drain feature 246N includes the bottom epitaxial feature 242 and an n-type main epitaxial feature 244N. The n-type main epitaxial feature 244N may include silicon (Si) and an n-type dopant, such as phosphorus (P), arsenic (As), or antimony (Sb). The p-type source/drain feature 246P includes the bottom epitaxial feature 242 and a p-type main epitaxial feature 244P. The p-type main epitaxial feature 244P may include silicon germanium (SiGe) and a p-type dopant, such as boron (B). Each of the n-type source/drain feature 246N and the p-type source/drain feature 246P may be in direct contact with a top surface of the base fin structure 212B and a sidewall of the gate spacer layer 226. For ease of illustration and description, the n-type source/drain feature 246N and the p-type source/drain feature 246P may be collectively referred to as the source/drain feature 246, as in FIG. 19.

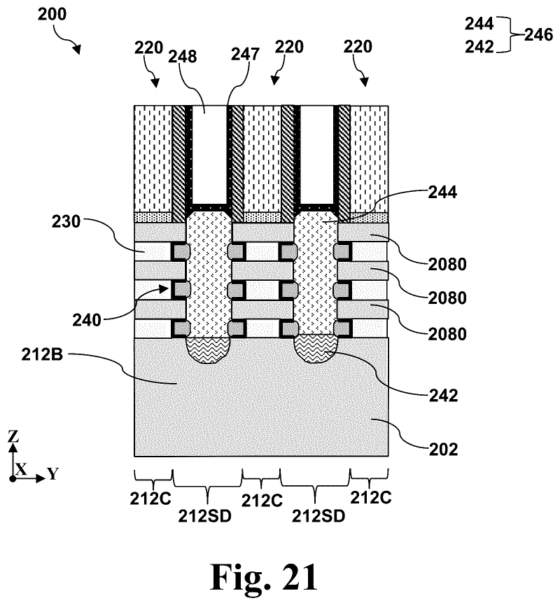

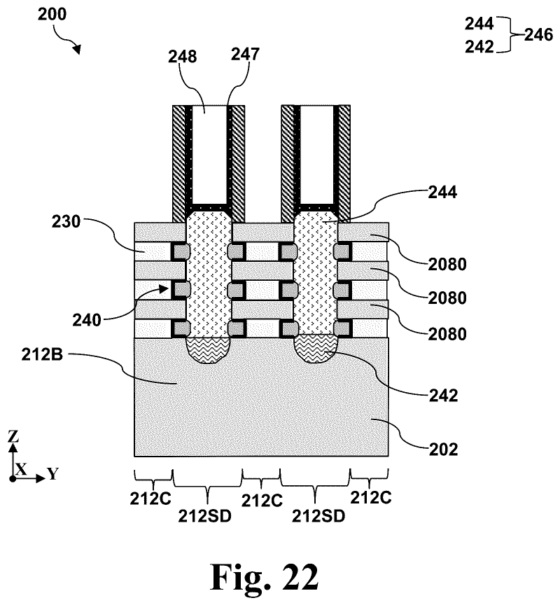

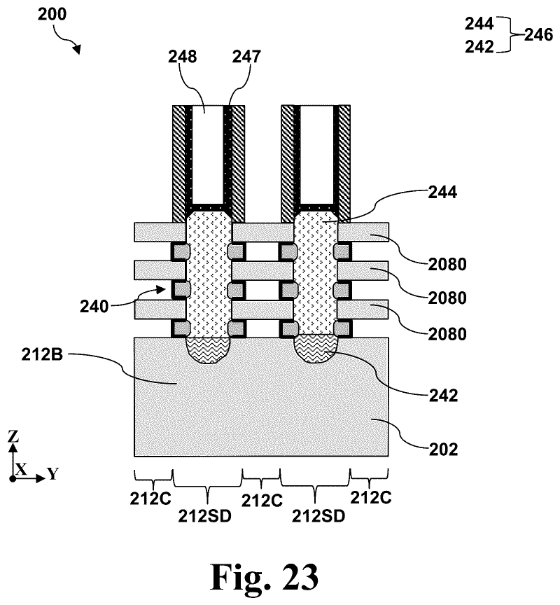

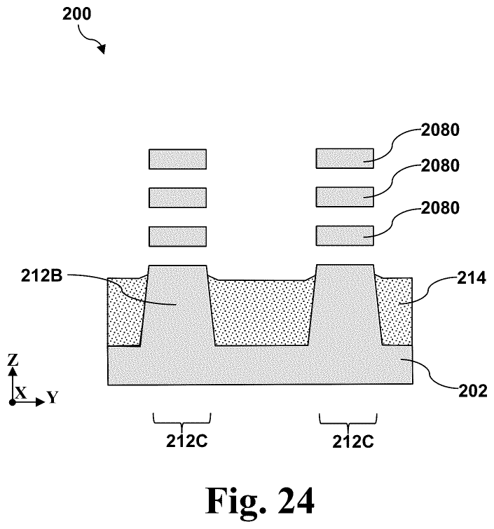

Referring to FIGS. 1 and 21-25, method 100 includes a block 130 where the dummy gate stack 220 and the dummy layer 230 are replaced with a gate structure 250. Operations at block 130 may include deposition of a contact etch stop layer (CESL) 247 over the source/drain features 246 (shown in FIG. 21), deposition of an interlayer dielectric layer 248 over the CESL 247 (shown in FIG. 21), removal of the dummy gate stack 220 (shown in FIG. 22), removal of the dummy layer 230 (shown in FIGS. 23 and 24), and deposition of the gate structure 250 to wrap around each of the channel members 2080 (shown in FIG. 25). Referring to FIG. 21, the CESL 247 is deposited over the WIP structure 200, including over the source/drain feature 246. The CESL 247 may include silicon nitride or aluminum nitride. In some implementations, the CESL 247 may be deposited using CVD or atomic layer deposition (ALD). The ILD layer 248 is then deposited over the CESL 247. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dummy layer 230 in the channel region 212C is exposed. A separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As described above, the selective etch of the dummy layer 230 etches the first inner spacer layer 234 at a much smaller rate. After the selective removal of the dummy layer 230, the channel members 2080 in the channel region 212C are once again exposed as shown in FIGS. 23 and 24.

After the release of the channel members 2080, the gate structure 250 is formed to wrap around each of the channel members 2080 as shown in FIG. 25. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

In one exemplary aspect, the present disclosure is directed to a method. The method includes forming over a substrate a stack that includes a plurality of channel layers interleaved by a plurality of sacrificial layers, patterning the stack and the substrate to form a fin-shaped structure having a base portion formed from the substrate and a stack portion formed from the stack, forming an isolation feature around the base portion, forming a dummy gate stack over a channel region of the fin-shaped structure, depositing a gate spacer layer over the dummy gate stack, after the depositing of the gate spacer layer, recessing a source/drain region of the fin-shaped structure, selectively removing the plurality of sacrificial layers in the channel region to release the plurality of channel layers as a plurality of channel members, depositing a dummy layer over the plurality of channel members, selectively and partially recessing the dummy layer to form inner spacer recesses among the plurality of channel members, depositing a first inner spacer layer over the inner spacer recesses, depositing a second inner spacer layer over the first inner spacer layer, etching back the first inner spacer layer and the second inner spacer layer to form inner spacer features in the inner spacer recesses, forming a source/drain feature over the source/drain region, removing the dummy gate stack, removing the dummy layer, and forming a gate structure to wrap around each of the plurality of channel members.

In some embodiments, the etching back etches the first inner spacer layer faster than the second inner spacer layer. In some embodiments, the second inner spacer layer includes silicon carbonitride, silicon oxycarbonitride, silicon nitride, silicon oxycarbide, or silicon oxynitride. In some embodiments, the first inner spacer layer includes boron carbon oxynitride or boron-doped silicon oxycarbonitride. In some implementations, the first inner spacer layer includes aluminum oxide. In some instances, the first inner spacer layer includes a boron-containing dielectric layer. In some embodiments, the first inner spacer layer includes polyethylene or polypropylene. In some embodiments, the depositing of the first inner spacer layer includes treating surfaces of the plurality of channel members, the substrate and the dummy layer to form dangling bonds and causing a precursor monomer to react with the dangling bonds.

In another exemplary aspect, the present disclosure is directed to a method. The method includes forming over a substrate a stack that includes a plurality of silicon layers interleaved by a plurality of silicon germanium layers, patterning the stack and the substrate to form a fin-shaped structure having a base portion formed from the substrate and a stack portion formed from the stack; forming an isolation feature around the base portion; forming a dummy gate stack over a channel region of the fin-shaped structure, depositing a gate spacer layer over the dummy gate stack, after the depositing of the gate spacer layer, recessing a source/drain region of the fin-shaped structure, selectively removing the plurality of silicon germanium layers in the channel region to release the plurality of silicon layers as a plurality of channel members, depositing a semiconductor oxide layer over the plurality of channel members, selectively and partially recessing the semiconductor oxide layer to form inner spacer recesses among the plurality of channel members, depositing a first inner spacer layer over the inner spacer recesses, depositing a second inner spacer layer over the first inner spacer layer, etching back the first inner spacer layer and the second inner spacer layer to form inner spacer features in the inner spacer recesses, forming a source/drain feature over the source/drain region, removing the dummy gate stack;, removing the semiconductor oxide layer, and forming a gate structure to wrap around each of the plurality of channel members.

In some embodiments, the second inner spacer layer includes silicon carbonitride, silicon oxycarbonitride, silicon nitride, silicon oxycarbide, or silicon oxynitride. In some embodiments, the first inner spacer layer includes a boron-containing dielectric layer. In some implementations, the boron-containing dielectric layer includes boron carbon oxynitride or boron-doped silicon oxycarbonitride. In some embodiments, a dielectric constant of the first inner spacer layer is smaller than a dielectric constant of the second inner spacer layer. In some embodiments, the etching back etches the first inner spacer layer faster than the second inner spacer layer.

In yet another exemplary aspect, the present disclosure is directed to a semiconductor structure. The semiconductor structure includes a base fin over a substrate, a first source/drain feature and a second source/drain feature over the base fin, a plurality of nanostructures extending between the first source/drain feature and the second source/drain feature, a gate structure wrapping around each of the plurality of nanostructures, and a plurality of inner spacer features interleaving the plurality of nanostructures. Each of the plurality of inner spacer features partially extends into the first source/drain feature.

In some embodiments, each of the plurality of inner spacer features includes a first inner spacer layer in contact with the gate structure and at least one of the plurality of nanostructures, and a second inner spacer layer spaced apart from the gate structure and the at least one of the plurality of nanostructures by the first inner spacer layer. In some embodiments, the second inner spacer layer includes silicon carbonitride, silicon oxycarbonitride, silicon nitride, silicon oxycarbide, or silicon oxynitride. In some implementations, the first inner spacer layer includes boron carbon oxynitride or boron-doped silicon oxycarbonitride. In some embodiments, the first inner spacer layer includes aluminum oxide. In some instances, the first inner spacer layer includes polyethylene or polypropylene.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack and the substrate to form a fin-shaped structure having a base portion formed from the substrate and a stack portion formed from the stack;
forming an isolation feature around the base portion;
forming a dummy gate stack over a channel region of the fin-shaped structure;
depositing a gate spacer layer over the dummy gate stack;
after the depositing of the gate spacer layer, recessing a source/drain region of the fin-shaped structure;
selectively removing the plurality of sacrificial layers in the channel region to release the plurality of channel layers as a plurality of channel members;
depositing a dummy layer over the plurality of channel members;
selectively and partially recessing the dummy layer to form inner spacer recesses among the plurality of channel members;
depositing a first inner spacer layer over the inner spacer recesses;
depositing a second inner spacer layer over the first inner spacer layer;
etching back the first inner spacer layer and the second inner spacer layer to form inner spacer features in the inner spacer recesses;
forming a source/drain feature over the source/drain region;
removing the dummy gate stack;
removing the dummy layer; and
forming a gate structure to wrap around each of the plurality of channel members.

2. The method of claim 1, wherein the etching back etches the first inner spacer layer faster than the second inner spacer layer.

3. The method of claim 1, wherein the second inner spacer layer comprises silicon carbonitride, silicon oxycarbonitride, silicon nitride, silicon oxycarbide, or silicon oxynitride.

4. The method of claim 2, wherein the first inner spacer layer comprises boron carbon oxynitride or boron-doped silicon oxycarbonitride.

5. The method of claim 2, wherein the first inner spacer layer comprises aluminum oxide.

6. The method of claim 2, wherein the first inner spacer layer comprises a boron-containing dielectric layer.

7. The method of claim 2, wherein the first inner spacer layer comprises polyethylene or polypropylene.

8. The method of claim 7, wherein the depositing of the first inner spacer layer comprises:
treating surfaces of the plurality of channel members, the substrate and the dummy layer to form dangling bonds; and
causing a precursor monomer to react with the dangling bonds.

9. A method, comprising:
forming over a substrate a stack that includes a plurality of silicon layers interleaved by a plurality of silicon germanium layers;
patterning the stack and the substrate to form a fin-shaped structure having a base portion formed from the substrate and a stack portion formed from the stack;
forming an isolation feature around the base portion;
forming a dummy gate stack over a channel region of the fin-shaped structure;
depositing a gate spacer layer over the dummy gate stack;
after the depositing of the gate spacer layer, recessing a source/drain region of the fin-shaped structure;
selectively removing the plurality of silicon germanium layers in the channel region to release the plurality of silicon layers as a plurality of channel members;
depositing a semiconductor oxide layer over the plurality of channel members;
selectively and partially recessing the semiconductor oxide layer to form inner spacer recesses among the plurality of channel members;
depositing a first inner spacer layer over the inner spacer recesses;
depositing a second inner spacer layer over the first inner spacer layer;
etching back the first inner spacer layer and the second inner spacer layer to form inner spacer features in the inner spacer recesses;
forming a source/drain feature over the source/drain region;
removing the dummy gate stack;
removing the semiconductor oxide layer; and
forming a gate structure to wrap around each of the plurality of channel members.

10. The method of claim 9, wherein the second inner spacer layer comprises silicon carbonitride, silicon oxycarbonitride, silicon nitride, silicon oxycarbide, or silicon oxynitride.

11. The method of claim 10, wherein the first inner spacer layer comprises a boron-containing dielectric layer.

12. The method of claim 11, wherein the boron-containing dielectric layer comprises boron carbon oxynitride or boron-doped silicon oxycarbonitride.

13. The method of claim 9, wherein a dielectric constant of the first inner spacer layer is smaller than a dielectric constant of the second inner spacer layer.

14. The method of claim 9, wherein the etching back etches the first inner spacer layer faster than the second inner spacer layer.

15. A semiconductor structure, comprising:
a base fin over a substrate;
a first source/drain feature and a second source/drain feature over the base fin;
a plurality of nanostructures extending between the first source/drain feature and the second source/drain feature;
a gate structure wrapping around each of the plurality of nanostructures; and
a plurality of inner spacer features interleaving the plurality of nanostructures,
wherein each of the plurality of inner spacer features partially extends into the first source/drain feature.

16. The semiconductor structure of claim 15, wherein each of the plurality of inner spacer features comprises:
a first inner spacer layer in contact with the gate structure and at least one of the plurality of nanostructures; and
a second inner spacer layer spaced apart from the gate structure and the at least one of the plurality of nanostructures by the first inner spacer layer.

17. The semiconductor structure of claim 16, wherein the second inner spacer layer comprises silicon carbonitride, silicon oxycarbonitride, silicon nitride, silicon oxycarbide, or silicon oxynitride.

18. The semiconductor structure of claim 17, wherein the first inner spacer layer comprises boron carbon oxynitride or boron-doped silicon oxycarbonitride.

19. The semiconductor structure of claim 17, wherein the first inner spacer layer comprises aluminum oxide.

20. The semiconductor structure of claim 17, wherein the first inner spacer layer comprises polyethylene or polypropylene.
